(19) United States
(12) Patent Application Publication
(10) Pub. No.: US 2024/0405143 A1
(43) Pub. Date: Dec. 5, 2024

(54) Solar Cells Incorporating FeOx Thin-Films

(71) Applicant: Blue Origin, LLC, Kent, WA (US)

(72) Inventors: Jeong Chul Lee, Monrovia, CA (US); Jean Choung, Los Angeles, CA (US); Alexander Imbault, Sierra Madre, CA (US); Jonathan Grandidier, Pasadena, CA (US)

(21) Appl. No.: 18/326,190

(22) Filed: May 31, 2023

(51) Int. Cl. H01L 31/072; H01L 31/18

(52) U.S. Cl. CPC H01L 31/072; H01L 31/1804; E21C 51/00

(57) ABSTRACT

A solar cell that incorporates a thin layer of iron oxide (FeOₓ), and a number of techniques for fabricating the solar cell, are presented. The thin layer of iron oxide, which may be derived from lunar regolith, may be the emitter of the solar cell. The solar cell may be a silicon hetero-junction (HJ) solar cell. The FeOₓ may be present in place of amorphous silicon (a-Si:H), MoOₓ, or various organic materials, for example. An emitter comprising FeOₓ may be beneficial for solar cell fabrication on the moon.

### BACKGROUND

Solar panels have become relatively commonplace as a means for generating electricity via the sun. Solar panels may comprise photovoltaic solar modules that absorb sunlight as a source of energy to generate direct current electricity. A photovoltaic module is a packaged, connected assembly of photovoltaic solar cells available in different voltages and wattages.

Solar cells have been, and continue to be, the main power source for most Earth orbiting satellites and probes into the solar system, since they provide a favorable power-to-weight ratio. Moreover, equipment and occupants in a space, lunar, or planetary environment have few other power options. Unfortunately, costs associated with bringing (e.g., launching) solar cells or panels into space from Earth are very high.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 is a schematic cross-section of a solar cell, according to some embodiments.

FIG. 2 is a schematic flow diagram of growing a lunar-based thin film onto a silicon substrate, according to some embodiments.

FIG. 3 is a flow diagram of growing a lunar-based thin film onto a silicon substrate, according to some embodiments.

FIG. 4 is a current-voltage (I-V) plot of a solar cell, according to some embodiments.

### DETAILED DESCRIPTION

This disclosure describes a solar cell that incorporates a thin layer of iron oxide and a number of techniques for fabricating the solar cell. For example, the thin layer of iron oxide may be the emitter of the solar cell. In some embodiments, the iron oxide may be derived from lunar regolith, as discussed below. Herein, the terms “iron oxide” and “FeOₓ” broadly refer to all stoichiometric combinations of iron and oxygen, unless otherwise specified. For example, iron oxide may be FeₓO_{y}, where x and y are any integers. For a specific example, iron (II) oxide or ferrous oxide has the formula FeO. Iron oxide in regolith may be Fe²⁺ (FeO), called Wüstite. Embodiments of solar cells, as described herein, may involve iron as a mixture of Fe²⁺ and Fe³⁺, both generically referred to herein as FeOₓ.

A solar cell, or photovoltaic cell, is an electronic device that converts the energy of light directly into electricity by the photovoltaic effect. Electrical characteristics, such as current, voltage, and resistance, vary when exposed to light. Individual solar cell devices are often the electrical building blocks of photovoltaic modules, such as solar panels. The operation of a photovoltaic (solar) cell involves three basic attributes: 1) The absorption of light to generate excitons (bound electron-hole pairs), unbound electron-hole pairs (via excitons), or plasmons. 2) The separation of charge carriers of opposite types. 3) The extraction of those carriers to an external circuit.

In embodiments described below, silicon hetero-junction (HJ) solar cells include an FeOₓ thin-film as an emitter. Generally, a silicon HJ solar cell may include an emitter comprising amorphous silicon (a-Si:H), MoOₓ, or various organic materials. An emitter comprising FeOₓ, however, may be beneficial under a number of circumstances. For example, FeOₓ is relatively abundant in lunar regolith. Thus, fabrication of solar cells on the moon would benefit from using this material as an emitter. FeOₓ is also relatively abundant on Earth, so there may be circumstance where Earth-bound solar cell fabrication would likewise benefit from using this material as an emitter.

Amorphous silicon (a-Si) is the non-crystalline form of silicon used for solar cells. Though crystalline forms of silicon thin-films may be used as an emitter for solar cells, their efficiency may be less compared to solar cells that use a-Si:H (hydrogenated amorphous silicon) as an emitter. Unhydrogenated a-Si generally has a very high defect density that leads to undesirable semiconductor properties such as poor photoconductivity. The high defect density may also prevent doping, which may be critical for some engineering semiconductor properties. By introducing hydrogen during the fabrication of amorphous silicon, photoconductivity is generally significantly improved and doping is made possible. In some implementations, use of an FeOₓ thin-film emitter may preclude the need to incorporate a-Si into a solar cell.

Solar cells may be p-type or n-type. The term p-type refers to the solar cell being built on a positively charged (p-type) silicon base. For example, the silicon base may be doped with boron (trivalent), which has one valence electron less than silicon (quadrivalent). The top of the silicon base may be negatively doped (n-type) with phosphorous (pentavalent), which has one valence electron more than silicon. This arrangement forms a p-n junction that will enable the flow of electricity in the solar cell. Other elements may be used for doping in different embodiments.

In some embodiments, as introduced above, a silicon hetero-junction solar cell includes a silicon substrate and an emitter that comprises an iron oxide thin film layer deposited on the silicon substrate. The iron oxide may be derived from lunar regolith. The solar cell may also include an indium tin oxide (ITO) layer deposited on the iron oxide thin film layer. Instead of ITO, other transparent conducting films may be used, such as conductive polymers, metal grids, and carbon nanotubes, just to name a few examples. In some implementations, the silicon substrate may be a p-type semiconductor and the iron oxide thin film layer may be an n-type emitter. In such a case, the iron oxide thin film layer may be doped with silicon dioxide (SiO₂). In other implementations, the silicon substrate may be an n-type semiconductor and the iron oxide thin film layer may be a p-type emitter. In such a case, the iron oxide thin film layer may be doped with magnesium oxide (MgO).

In some embodiments, a method for fabricating a silicon hetero-junction solar cell may include vaporizing iron oxide and depositing the iron oxide onto a silicon substrate to form an iron oxide thin film emitter for the silicon hetero-junction solar cell. The vaporization and deposition may be performed in the vacuum that exists on the moon. On Earth, however, an artificial vacuum may be provided to the vaporization and deposition processes. The iron oxide may be derived from lunar regolith, or minerals found on off-Earth locations and/or objects in the Solar System, such as asteroids, moons, minor-planets, and planets, among other such objects. In such an example case, regolith may be harvested from the lunar surface and iron oxide minerals may be separated out by any of a number of techniques, such as molten oxide electrolysis (MOE), molten regolith electrolysis (MRE), high-gradient magnetic separation, or flotation processes, for example. The iron oxide may then be isolated from the iron oxide minerals or the iron oxide minerals themselves may be used in the vaporization process. In other embodiments, regolith harvested from the lunar surface may be processed to separate out iron-bearing minerals, which may be subsequently reduced to substantially pure iron and oxygen, which may then be recombined to a particular mixture of Fe²⁺ and Fe³⁺ at a specific ratio and at specific conditions to produce a desired mixture, for example. These processes may be performed on the moon.

In some examples of the vaporization process, conditions of the vaporizing of the iron oxide may be varied so as to vary the stoichiometry (e.g., the proportions) of Fe and O. For example, reacting iron oxide with oxygen (e.g., from a different mineral derived from the lunar regolith) at particular vaporization temperatures may yield iron (III) oxide. Moreover, additional thermal treatments may yield various phase structures, such as alpha or gamma phases, which may behave in particular ways as an emitter in the solar cell. In some embodiments, the vaporization and deposition processes may be performed such that gases (e.g., oxygen, boron, hydrogen, etc.) are not reacted with any portion of the silicon hetero-junction solar cell. Claimed subject matter is not limited to any particular material compositions, deposition methods, or post-treatment of FeOₓ. For example, a process of fabricating FeOₓ solar cells may involve e-beam evaporation, though sputtering may be an alternative process for FeOₓ deposition.

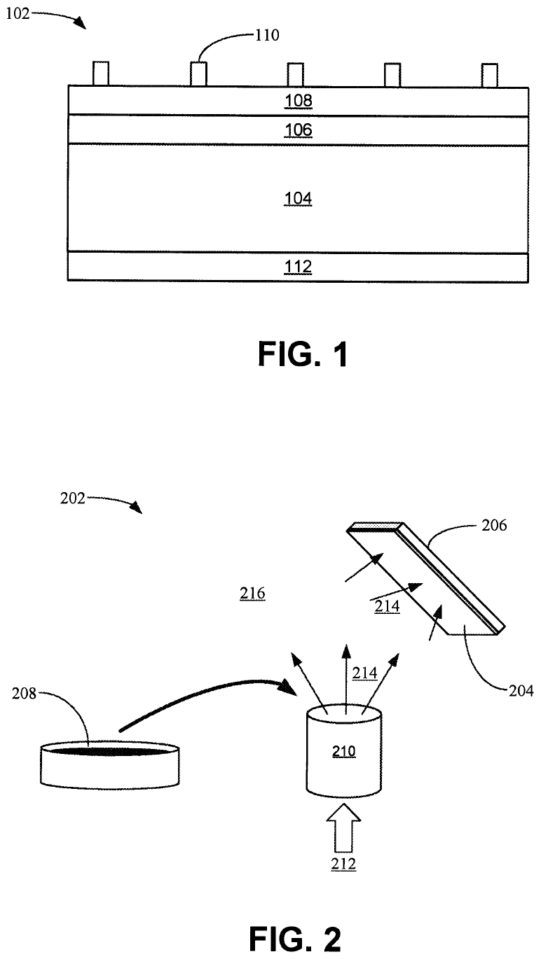

FIG. 1 is a schematic cross-section of a silicon hetero-junction solar cell 102, according to some embodiments. Solar cell 102 includes a silicon substrate 104, which may be formed from a silicon wafer. An iron oxide emitter 106 is deposited on the silicon substrate. An at least partially transparent conductive material, such as ITO 108 may overlay the iron oxide emitter. Conductive contacts 110 may be electrically connected to ITO 108. In some implementations, a metallic layer 112, such as aluminum may be disposed on silicon substrate 104, on the side opposite to that of iron oxide emitter 106, as a rear electrical contact.

In some implementations, silicon substrate 104 may be p-type and iron oxide emitter 106 may be n-type. In other implementations, silicon substrate 104 may be n-type and iron oxide emitter 106 may be p-type. In other implementations, semiconductor materials other than silicon (e.g., germanium) may be used, and claimed subject matter is not limited to any particular substrate material.

Dimensions of the various parts of solar cell 102 are not illustrated to scale. For example, silicon substrate 104 may be about 180 microns thick and the thickness of iron oxide emitter 106 may be in a range of about 3 to 20 nanometers (nm). ITO 108 may have a thickness of about 80 nm, though claimed subject matter is not limited to any of these values.

FIG. 2 is a schematic flow diagram of a process 202 of growing a lunar-based thin film 204 onto a silicon substrate 206, according to some embodiments. A silicon hetero-junction solar cell (e.g., 102) may be fabricated from lunar-based thin film 204 and silicon substrate 206 by the addition of front and rear electrical contacts and, in some implementations, doping elements. Lunar-based thin film 204 may be iron oxide derived from lunar regolith harvested from the moon surface. After isolating iron oxide 208 from iron oxide minerals that are separated out from the harvested regolith, the iron oxide is transferred to a vaporization unit 210. Heat 212 is supplied to the vaporization unit to heat and vaporize the iron oxide.

The vaporized iron oxide 214 is deposited onto silicon substrate 206 to form thin film 204, which is condensed iron oxide 214. Process 202 may be performed in a vacuum 216 of the moon.

As mentioned above, the vaporization process, performed by vaporization unit 210, may involve altering conditions, such as the duration and temperature of the applied heat 212, for vaporizing the iron oxide. Conditions may be altered to vary the stoichiometry of Fe and O.

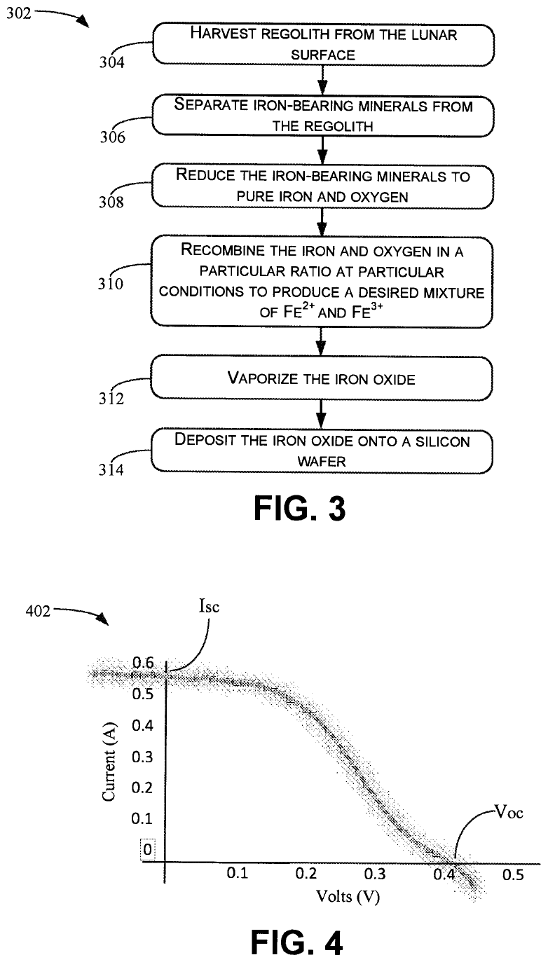

FIG. 3 is a flow diagram of a process 302 of growing lunar-based thin film 204 onto silicon substrate 206, according to some embodiments. Process 302, which may be performed by an operator that is human, a computer processor, or a combination of both, may involve steps leading from regolith to a Fe²⁺ and Fe³⁺ mixture, for example.

At 304, the operator may harvest regolith from the lunar surface. Such harvesting may be a mining process of scooping up relatively large quantities of regolith and collecting the material into bins for the following separation and isolation treatments. At 306, the operator may separate out iron-bearing minerals from the bulk regolith. For example, such iron-bearing minerals may be pyroxene, olivine, or ilmenite, just to name a few possibilities. At 308, the operator may reduce the iron-bearing minerals to substantially pure iron and oxygen. At 310, the operator may recombine the iron and oxygen in a particular ratio at particular conditions to produce a desired mixture of Fe²⁺ and Fe³⁺. At 312, the operator may vaporize iron oxide, such as by using vaporization unit 210. At 314, the operator may deposit the vaporized iron oxide onto silicon substrate 206 (e.g., a silicon wafer).

FIG. 4 is a current-voltage (I-V) plot 402 of solar cell 102, according to some embodiments. Solar cell I-V plot 402 demonstrates an example relationship between the current and voltage across the solar cell at particular conditions of irradiance and temperature. For instance, the short-circuit current, Isc, and the open-circuit voltage, Voc, are identified in the plot for the solar cell's particular ambient conditions. Plot 402 illustrates an example performance of a solar cell with an FeOₓ emitter on a silicon wafer. The conversion efficiency is 6.2% with 0.387V Voc, 36.7 mA/cm2 Jsc (short-circuit current density), and 43.4% FF (fill factor)

The foregoing description, for purposes of explanation, used specific nomenclature to provide a thorough understanding of the disclosure. However, it will be apparent to one skilled in the art that the specific details are not required in order to practice the systems and methods described herein. The foregoing descriptions of specific embodiments or examples are presented by way of examples for purposes of illustration and description. They are not intended to be exhaustive of or to limit this disclosure to the precise forms described. Many modifications and variations are possible in view of the above teachings. The embodiments or examples are shown and described in order to best explain the principles of this disclosure and practical applications, to thereby enable others skilled in the art to best utilize this disclosure and various embodiments or examples with various modifications as are suited to the particular use contemplated. It is intended that the scope of this disclosure be defined by the following claims and their equivalents.

1. A silicon hetero-junction solar cell comprising:
a silicon substrate; and
an emitter comprising an iron oxide (FeOₓ) thin film layer deposited on the silicon substrate.

2. The silicon hetero-junction solar cell of claim 1, wherein the silicon substrate is a p-type semiconductor and the FeOₓ thin film layer is an n-type emitter.

3. The silicon hetero-junction solar cell of claim 2, wherein the FeOₓ thin film layer includes silicon dioxide (SiO₂).

4. The silicon hetero-junction solar cell of claim 1, wherein the silicon substrate is an n-type semiconductor and the FeOₓ thin film layer is a p-type emitter.

5. The silicon hetero-junction solar cell of claim 4, wherein the FeOₓ thin film layer includes magnesium oxide (MgO).

6. The silicon hetero-junction solar cell of claim 1, further comprising an indium tin oxide (ITO) layer deposited on the FeOₓ thin film layer.

7. The silicon hetero-junction solar cell of claim 1, wherein the FeOₓ thin film layer is derived from lunar regolith.

8-14. (canceled)

15. A silicon hetero-junction solar cell comprising:
a silicon substrate;
a thin film emitter layer comprising lunar regolith-derived iron oxide (FeOₓ) deposited on the silicon substrate;
an at least partially transparent conductive layer on the thin film emitter layer; and
electrical contacts attached to the at least partially transparent conductive layer.

16. The silicon hetero-junction solar cell of claim 15, wherein the at least partially transparent conductive layer comprises indium tin oxide (ITO).

17. The silicon hetero-junction solar cell of claim 15, wherein the silicon substrate is a p-type semiconductor and the thin film emitter layer is an n-type emitter.

18. The silicon hetero-junction solar cell of claim 17, wherein the thin film emitter layer includes silicon dioxide (SiO₂).

19. The silicon hetero-junction solar cell of claim 15, wherein the silicon substrate is an n-type semiconductor and the thin film emitter layer is a p-type emitter.

20. The silicon hetero-junction solar cell of claim 19, wherein the thin film emitter layer includes magnesium oxide (MgO).

21. A solar cell comprising:
a silicon substrate;
a thin film emitter layer comprising iron oxide, the thin film emitter layer disposed on the silicon substrate;
an indium tin oxide (ITO) layer deposited on the thin film emitter layer; and
electrical contacts attached to the ITO layer.

22. The solar cell of claim 21, wherein the silicon substrate is a p-type semiconductor and the thin film emitter layer is an n-type emitter.

23. The solar cell of claim 21, wherein the thin film emitter layer includes silicon dioxide (SiO₂).

24. The solar cell of claim 21, wherein the silicon substrate is an n-type semiconductor and the thin film emitter layer is a p-type emitter.

25. The solar cell of claim 24, wherein the thin film emitter layer includes magnesium oxide (MgO).

26. The solar cell of claim 21, wherein the iron oxide in the thin film emitter layer comprises iron (iii) oxide.

27. The solar cell of claim 21, wherein the iron oxide in the thin film emitter layer is derived from lunar regolith.
